(19) United States
(12) Patent Application Publication
(10) Pub. No.: US 2016/0301023 A1
(43) Pub. Date: Oct. 13, 2016

(54) PHOTOVOLTAIC DEVICES BASED ON ORGANO-METALLIC MOLECULES

(71) Applicant: Struya Sol Corporation, San Carlos, CA (US)

(72) Inventor: Branimir SIMIC-GLAVASKI, Cleveland Heights, OH (US)

(21) Appl. No.: 15/100,708

(22) PCT Filed: Nov. 25, 2014
(86) PCT No.: PCT/US14/67369

§ 371 Date: Jun. 2, 2016

Related U.S. Application Data
(60) Provisional application No. 61/911,118, filed on Dec. 3, 2013.

(51) Int. Cl. H01L 51/42; H01L 51/00

(52) U.S. Cl. CPC H01L 51/4206; H01L 51/0091; H01L 51/0083

(57) ABSTRACT

A photovoltaic device and method for making it include organo-metallic molecules, such as M-Ph (metallo-phthalocyanines) and/or M-Pc (metallo-porphyrins), that interact with clusters, which are at the surface of a bulk metal, enhancing photovoltaic effect and increasing efficiency for transformation of radiant energy into electricity. Interaction of the clusters and the M-Ph and/or M-Pc increases quantum efficiency in transforming radiant energy into electricity. Methods are provided for treatment of a bulk metal, e.g., silver, gold or copper, from a metallic state to a state where clusters are formed on the surface of the bulk metal, and the organo-metallic molecules and a transparent conductor are applied to make the photovoltaic device.

### TECHNICAL FIELD

The present disclosure relates generally to solar cells based on organo-metallic molecules and, more particularly, to photovoltaic devices responsive to radiant energy to undergo photovoltaic effect and methods for making and using.

### BACKGROUND

There is a need to increase and to improve devices and methods for producing electricity. Many products require electricity for operation, e.g., computers, games, communication devices, such as mobile phones and the like, vehicles, and so on.

Photovoltaic devices provide electrical output, e.g., electric potential or voltage, in response to a radiant energy input. Electric potential and voltage are used equivalently and interchangeably herein. As an example, the radiant energy input may be light in the visible spectrum and/or radiant energy that is in the non-visible spectrum, e.g., ultraviolet, infrared or other spectrum. The electrical output may be used in various devices and for various purposes, e.g., to charge a battery, to power a mobile phone, to provide electrical input to an electric circuit, and so on.

Organo-metallic molecules, such as metallo-porphyrins (sometimes abbreviated “M-Ph”) and metallo-phthalocyanines (sometimes abbreviated “M-Pc”) have photovoltaic properties. In response to radiant energy input they provide electrical output.

Organo-metallic molecules such as M-Ph or M-Pc in which the metal can be hydrogen, iron, cobalt, lead, nickel, and so on are highly versatile molecular structures with potential applications in catalysts, information storage devices, molecular devices, photo-voltaic devices, sensors, photodynamic tumor therapy and other applications.

The molecular structure of M-Ph and M-Pc is very similar to heme or chlorophyll structures which exist in nature. Additions of four benzene rings to the basic porphyrin molecules make them highly stable from the temperature of liquid Helium (He) to about 800 C in vacuum. In addition they are resistive to radiation of (α, β and γ type—i.e., alpha, beta and gamma type).

Phthalocyanine molecules (sometimes referred to as phthalocyanines) and porphyrin molecules (sometimes referred to as porphyrins) can be obtained from Eastman Kodak, Sigma Aldrich and other chemical companies. As an example, usually metallo-phthalocyanines (M-Pc) are in the form which is soluble in some organic solvents, such as dimethyl sulfoxide (DMSO), and in strong acid, such as H₂SO₄ (sulfuric acid), HCl (hydrochloric acid) and some others. In their sulphonated form, usually tetra-sulphonated (sometimes abbreviated “M-TsPc” representing tetra-sulphonated metallo-phthalocyanines), they are soluble in aqueous solutions that are user friendly.

A cluster (sometimes referred to as a metal cluster) is an ensemble of bound metal atoms intermediate in size between a molecule and a bulk solid. Another definition of a cluster is a compound in which two or more metal atoms aggregate so as to be within bonding distance of one another, and each metal atom is bonded to at least two other metal atoms; some nonmetal atoms may be associated with the cluster.

Reference is made to the following U.S. Pat. No. 7,136,212, No. 4,855,243, and No. 4,804,930, which disclose background information and which hereby are incorporated in their entirety by this reference.

### SUMMARY

Organo-metallic molecules, such as M-Ph and/or M-Pc, interact with clusters, which are at the surface of a bulk metal, enhancing photovoltaic effect and increasing efficiency for transformation of radiant energy into electricity. Interaction of the clusters and the M-Ph and/or M-Pc increases quantum efficiency in transforming radiant energy into electricity.

Methods are provided for treatment of a bulk metal, e.g., silver, gold or copper, from a metallic state to a state where clusters are formed on the surface of the bulk metal.

Methods are provided for treatment of metallic salts like a variety of metal halides such as, for example, AgBr or AgCl.

Methods also are provided for making a device including a bulk metal, clusters, and organo-metallic molecules, which may include a type of macrocyclic molecules.

Moreover, methods are provided for making a sandwich or stack of parts forming a photovoltaic device, including in sequential relation a base metal, clusters, organo-metallic molecules and a radiant energy transparent conductor.

A worldwide energy problem exists in that cost for energy continues to increase, e.g., cost for carbon fuels, cost for large renewable energy devices, such as windmills and geothermal systems, and so on, and some energy resources tend toward depletion, e.g., as oil fields and natural gas fields.

Another problem exists with respect to portable energy supplies, e.g., batteries, which include various chemicals and require or at least specify specific disposal arrangements to minimize environmental pollution.

According to an aspect of the technology of this disclosure, a photovoltaic device includes bulk metal having metallic clusters on the surface of the bulk metal, and organo-metallic molecules on the metallic clusters and responsive to radiant energy to undergo photovoltaic effect.

According to another aspect, a conductor is in position relative to the organo-metallic molecules to pass radiant energy to the organo-metallic molecules, whereby in response to radiant energy the organo-metallic molecules undergo photovoltaic effect transforming radiant energy to electric potential, and wherein the organo-metallic molecules and metal clusters are cooperative to increase the efficiency of the photovoltaic effect.

According to another aspect, the device is a stacked sequence of the bulk metal, metallic clusters, organo-metallic molecules, and conductor.

According to another aspect, a voltage output is obtained between the conductor and the bulk metal in response to radiant energy applied to the organo-metallic molecules via the conductor.

According to another aspect, the conductor includes indium tin oxide.

According to another aspect, the conductor includes an ionomer.

According to another aspect, the ionomer includes tetrafluoroethylene based fluoropolymer-copolymer.

According to another aspect, the ionomer includes nafion.

According to another aspect, in response to radiant energy holes and electrons are produced such that the holes tend to migrate to the conductor and the electrons tend to migrate to the bulk metal.

According to another aspect, the organo-metallic molecules include a number of different types of organo-metallic molecules, the respective types having different respective wavelength absorption characteristics.

According to another aspect, the wavelength absorption characteristics are wavelength absorption peaks, and the photovoltaic voltage output characteristics of respective organo-metallic molecules at least generally correspond to respective wavelength absorption peaks.

According to another aspect, a combination of the organo-metallic molecules having different wavelength absorption characteristics increases the number and/or range of radiant energy wavelengths over which the device provides photovoltaic voltage output.

According to another aspect, the organo-metallic molecules include phthalocyanine molecules.

According to another aspect, the phthalocyanine molecules includes metallo-phthalocyanine molecules.

According to another aspect, the phthalocyanine includes at least one of iron phthalocyanine molecules, cobalt phthalocyanine molecules or copper phthalocyanine molecules.

According to another aspect, the organo-metallic molecules include porphyrin molecules.

According to another aspect, the organo-metallic molecules include a mix (sometimes referred to as a mixture) of phthalocyanine molecules and porphyrin molecules.

According to another aspect, the organo-metallic molecules are responsive to radiant energy in the visible light spectrum.

According to another aspect, the base metal includes at least one of copper, silver or aluminum.

According to another aspect, the device is capable of withstanding temperatures while still being operative to produce a photovoltaic response at a temperature that exceeds 500 degrees Kelvin.

According to a further aspect, a method of forming clusters on a base metal, includes placing polycrystalline silver into hydrogen peroxide that is about 30% by volume water for a period of time.

According to still further aspects, the period of time is from about 20 seconds to about one minute; and/or wherein the period of time is from about 30 seconds to about one minute.

Another aspect relates a method of forming clusters on a base metal, includes placing polycrystalline bulk silver into a liquid electrolyte that is from about 0.05 to about 0.1 molar sulfuric acid or hydrochloric acid, the bulk silver is kept at a potential of from about 0.2 volts to about 0.5 volts vs. a saturated calomel electrode (SCE) for a period of time.

A further aspect relates to the period of time is from about a few seconds to about one minute.

According to another aspect, a method of forming clusters on a base metal, includes placing bulk metal of silver, copper or gold in an electrolyte comprising at least one of 0.1 M of perchloric acid or 0.05 M H₂SO₄; maintaining the potential at about the hydrogen evolution potential, which is about 1.5 volts, for a time period.

Another aspect relates to the period being from about several seconds to about 1 minute.

Another aspect relates to a method of forming clusters on a base metal, including exposing the base metal to photooxidation to form the clusters on the base metal.

Other aspects relate to after the clusters are provided on the base metal, applying organo-metallic molecules to the clusters; and/or applying an electrode to the organo-metallic molecules to form a photovoltaic device; and/or wherein the organo-metallic molecules comprise at least one organo-metallic phthalocyanine, organo-metallic porphyrin, tetra-sulphonated metallo-phthalocyanine or a combination of one or more thereof having different absorption peaks.

Another aspect relates to a method of making a sandwich cell of a photovoltaic device that includes indium tin oxide, tetra sulphonated metallo-phthalocyanine and a base metal electrode of silver or gold, including forming metal clusters on the base metal electrode by exposing the base metal electrode to a solution of “Pyrana” 70:30% concentrated sulfuric acid H2SO4 and H2O2 30% volume concentration for from about 30 seconds to about 60 seconds, and then washing the base metal in distilled water, applying organic-metallo molecules to the clusters that are formed on the base metal; and applying a conductor layer to the organic metallo molecules.

Other aspects relate to the applying a conductor layer including applying ITO, and/or wherein the base metal is a thin foil of silver or gold or the base metal is a metal deposited on flexible Mylar material.

Still another aspect relates to a method of forming clusters on a base metal, including submerging a cleaned and polished silver electrode of about 99.99% purity in an electrolyte of about 0.01M HClO4, submitting to electrochemical cyclic voltammetry between about −0.6 and about −0.2 V versus SCE (saturated calomel electrode) reference electrode where Au (gold) is a counter electrode; and after from about 10 to about 20 cycles of the cyclic voltammetry applying about 0.5 V potential for about 50 seconds; and washing in distilled water and drying or allowing to dry.

Still other aspects relate to wherein the silver electrode comprises a cleaned and polished polycrystalline silver electrode and/or wherein the silver electrode comprises a thin layer of silver on a Mylar material, and/or wherein the silver electrode comprises silver plating on a zinc conductor or an aluminum conductor.

Another aspect relates to a method of forming a cluster on a gold electrode, including cleaning the gold electrode in sulfuric acid (H2SO4), washing the cleaned gold electrode in distilled water, placing the gold electrode in an electrolyte and submitting it to cyclic voltammetry, and then washing the gold electrode metal in distilled water, leaving the gold electrode with gold clusters at the surface.

Other aspects relate to one or more of wherein the gold electrode is of about 99.99% purity gold in the form of a thin foil; and/or wherein said cleaning comprises cleaning the gold electrode in 1M H2SO4; and/or wherein said submitting to cyclic voltammetry includes submitting to
a) first potential E1 of −0.5 V (volts) for 60 second
b) a ramp potential of V1=1 V/sec to
c) E2 potential of 1.2 V for two seconds, and then to
d) a declining potential ramp V2=0.5V/sec to the original potential E1.

Another aspect relates to the submitting including repeating steps a through d from about 20 times to about 100 times.

Another aspect of the methods includes applying metallo organic molecules to the clusters, including applying solutions of phthalocyanines and porphyrins and ITO to the clusters that are on the base metal electrode, including spreading a solution of electrolyte about 0.01.M HClO4 containing from about 10⁻³M to about 10⁻⁵M of water soluble M-TsPc or porphyrin molecules M-Pc is spread (e.g., spin coating or simple brushing) on clusters on the silver or gold electrodes and then applying a cap of ITO.

Other aspects relate to the spreading including spin coating or brush coating; and/or sealing the edges to prevent evaporation; and/or increasing the number of and/or range of absorption spectrum/spectra by selecting the organo-metallic molecules as a mixture of plural M-TsPc, porphyrin or even combination of M-TsPc/M-Pc that have different absorption peaks.

These and further aspects and features of the present invention will be apparent with reference to the following description and attached drawings. In the description and drawings, embodiments of the invention have been disclosed in detail as being indicative of some of the ways in which the principles of the invention may be employed, but it is understood that the invention is not limited correspondingly in scope. Rather, the invention includes all changes, modifications and equivalents coming within the spirit and terms of the appended claims.

Features that are described and/or illustrated with respect to one embodiment may be used in the same way or in a similar way in one or more other embodiments and/or in combination with or instead of the features of the other embodiments.

It should be emphasized that the term “comprises/comprising” when used in this specification is taken to specify the presence of stated features, integers, steps or components but does not preclude the presence or addition of one or more other features, integers, steps, components or groups thereof.

Many aspects of the invention can be better understood with reference to the attached drawings. The components in the drawings are not necessarily to scale, emphasis instead being placed upon clearly illustrating the principles of the present invention. To facilitate illustrating and describing some parts of the invention, corresponding portions of the drawings may be exaggerated in size, e.g., made larger in relation to other parts than in an exemplary device actually made according to the invention. Elements and features depicted in one drawing or embodiment of the invention may be combined with elements and features depicted in one or more additional drawings or embodiments. Moreover, in the drawings, like reference numerals designate like or corresponding parts throughout the several views and may be used to designate like or similar parts in more than one embodiment. Primed reference numerals or reference numerals with a suffix letter, e.g., “a” designate parts that are similar to those designated by the same unprimed or “without a suffix” reference numeral.

### BRIEF DESCRIPTION OF THE DRAWINGS

In the annexed drawings, which are not to scale:

FIG. 1 is a schematic exploded view of a photovoltaic device;

FIG. 2 is a schematic view of a photovoltaic device in a circuit with a voltmeter;

FIG. 3 is a schematic energy diagram illustrating quantum energy levels in respective parts of the photovoltaic device and emitting of light;

FIG. 4A is a schematic view of a photovoltaic device in a circuit with a load;

FIG. 4B is a schematic illustration of a number of photovoltaic devices connected as one photovoltaic unit to power a load;

FIG. 4C is a schematic illustration of a number of photovoltaic devices connected together to provide an output; and

FIGS. 5A and 5B are graphical representations of incident illumination and electrical response of respective organo-metallic photovoltaic molecules showing respective absorption peaks and corresponding electrical outputs for several different molecules.

### DESCRIPTION

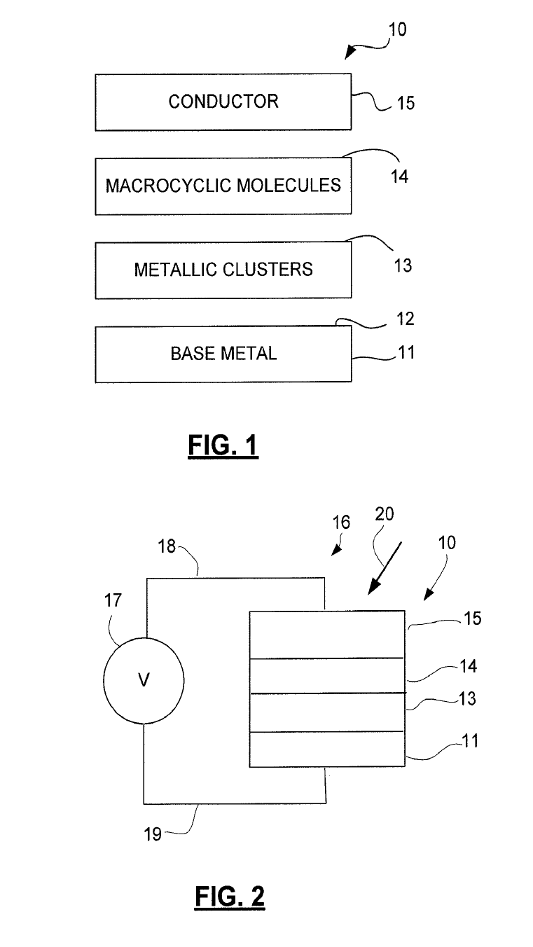

Referring to the drawings, which are not to scale and wherein like reference numerals designate like parts in the figures, and initially to FIG. 1, a photovoltaic is illustrated. The photovoltaic device 10 includes bulk metal 11 (also referred to as base metal) having a surface 12, metallic clusters 13 on the surface of the bulk metal, and organo-metallic molecules 14 on the metallic clusters. The clusters are a separate zone at the surface of the bulk metal. The organo-metallic molecules 14 are of the type that are responsive to radiant energy to undergo photovoltaic effect. A conductor 15 is in position relative to the organo-metallic molecules 14 to pass radiant energy to the organo-metallic molecules and to provide a connection for electrical output from the photovoltaic device 10. Although the parts or layers 12-15 are illustrated the same thickness for convenience of illustration, the actual thicknesses of the layers may be different, even very different from each other.

In operation of the photovoltaic device 10, radiant energy is passed through the conductor to the organo-metallic molecules 14. In response to radiant energy the organo-metallic molecules undergo photovoltaic effect transforming radiant energy to electric potential.

As is described further below, the clusters 13 on the bulk metal (base metal), which also may be referred to as the bulk metal electrode or base metal electrode, e.g., a silver electrode or gold electrode increases quantum efficiency of the sandwiched solar cell/photovoltaic cell 10.

Moreover, as is described further below using a mixture of phthalocyanines and/or porphyrins that have different absorption peaks increases spectral width and light harvesting power of the photovoltaic device 10.

Further using solutions/electrolytes of phthalocyanines and porphyrins may reduce production costs for the photovoltaic device 10.

FIG. 2 illustrates a photovoltaic device 10 in a circuit 16 with a voltmeter 17. Electrical leads 18, 19 connect the photovoltaic device to respective terminals of the voltmeter, e.g., to respective positive and negative terminals. In response to radiant energy 20 impinging on or incident on the photovoltaic device 10, the photovoltaic device produces an electric potential that can be measured and displayed by the voltmeter 17.

Continuing to refer to FIGS. 1 and 2, the nature of the clusters is such that they may be, for example, 1, 2, 5, 10 or even as many as 15 atoms of metal material, e.g., silver, gold, copper or aluminum. Possibly the number of atoms in a cluster may be even greater, provided the operative function described herein is obtained. The clusters are not crystalline or polycrystalline. Rather, the clusters are like a sponge—they are units of metal including a few atomic metal atoms up to about 10 or 15 atoms in a cluster. A difference between the base metal and the clusters on the base metal can be quantified on a quantum mechanics level. From a quantum mechanics point of view, the clusters have a different energy level than the base metal. From a visual point of view, a mirror made of silver may be reflective, whereas clusters on a mirror of silver would be milky white and would be soft and powdery.

The clusters 13 cover the entire surface 12, e.g., the top surface, of the bulk metal without any gaps.

In the photovoltaic device 10, the clusters and the organo-metallic molecules thereon may be protected by the conductor 15 from being damaged.

The organo-metallic molecules may be applied to the clusters by any of various techniques. Examples include painting on with a brush, spin coating (placing s quantity of organo-metallic molecules on the clusters and spinning the device, e.g., the base metal and clusters with the organo-metallic molecules thereon), electrochemical deposition, and/or possibly other techniques that exist or may come into existence in the future.

The organo-metallic molecules 14 and the metallic clusters 13 are cooperative to increase the efficiency of the photovoltaic effect beyond the photovoltaic effect seen when the organo-metallic molecules are directly on the bulk metal without clusters. The combination of the treated bulk metal to form the new state of clusters on the surface of the bulk metal and the photovoltaic photosensitive very stable phthalocyanine molecules and porphyrin molecules increases the quantum efficiency of those molecules and, thus, increases the efficiency of transforming light into electricity. Thus, the photovoltaic effect of the organo-metallic molecules is enhanced by using a base metal with clusters on which the organo-metallic molecules are placed.

As is seen in FIG. 1, the bulk metal 11, metallic clusters 13, organo-metallic molecules 14 and conductor 15 of the photovoltaic device 10 are arranged in a stack, stacked sequence, stacked relation or sandwich relation. In operation the photovoltaic device 10 provides a voltage output or electric potential that is obtained between the conductor 15 and bulk metal 11 in response to radiant energy (also sometimes as radiation) applied to the organo-metallic molecules 14 via the conductor. The radiant energy may be light in part or all of the visible spectrum, selected wavelengths of light in the visible spectrum, radiant energy in the non-visible spectrum, and so on; the radiant energy is of a character, e.g., wavelength, such that the organo-metallic molecules 14 respond to such radiant energy impinging or incident (impinging, incident, shining on, and so on may be used equivalently and interchangeably herein) thereon to undergo a photovoltaic effect and thereby to provide an electric potential or voltage output.

In the description below several documents are identified as relating to the particular description. The documents are incorporated in their entirety by the respective references to them.

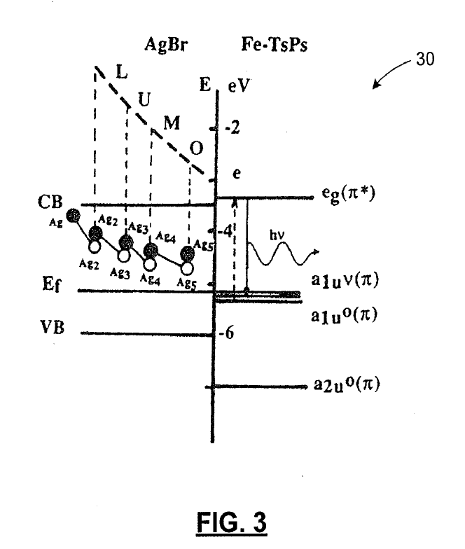

FIG. 3 is a diagram of the energy levels for the AgBr/Fe-TsPc interface. VB, CB and Ef are valence, conduction and Fermi levels, respectively. Agₙ are silver clusters, and a₁ᵤ(π) and e_{g}(π*) are occupied ground and excited phthalocyanine levels. Raman radiation hv originates from the transition e_{g}(π*) to the vibrational level a₁ᵤ(π).

Referring to FIG. 3, a graphical representation 30 provides analysis of the electronic energy levels in semiconducting AgBr and the adsorbed Fe-TsPc, as illustrated, for example, provides a more detailed and deeper insight into the mechanism of clusters formation involved in both photography and surface-enhanced Raman scattering. The Fermi level for AgBr is around −5 eV (see, for example, W. Jaenicke, in Advances in Electrochemistry and Electrochemical Engineering, H. Gerischer and C. W. Tobias Eds., 10,91, John Wiley and Sons, New York, 1977, which is incorporated in its entirety by reference. Energy levels E are represented in electron volts on the vertical axis in the graphical representation 30. The effect of the reducing developer on the AgBr plates is to form silver clusters and Agₙ and Agₙ₊ aggregates. The energy levels of the silver clusters' latent images are shown in FIG. 3. See, for example, B. Simic-Glavaski, J. Phys. Chem, 90 (1986) 3863, which is incorporated in its entirety by reference. According to the theory of photography W. Jaenicke, supra, B. Simic-Glavaski, supra, it appears that silver clusters are responsible for the photographic and surface-enhancing mechanisms and specific quantum properties.

The common phenomenon in the formation of silver substrates involving electrochemical (anodic and cathodic), chemical, and photoactivation is the formation of silver Ag+ and silver clusters Agₙ. See, for example, J. H. Webb, J. Opt. Soc. Am., 40 (1950) 3, which is incorporated in its entirety by reference. Neutral silver clusters Agₙ release an electron with an energy according to the scheme Agₙ+hv--->Ag+ₙ₊₁+e (see, for example, W. Jaenicke, supra, B. Simic-Glavaski, supra, this electron passes into the lowest unoccupied s molecular orbitals which are in the AgBr conduction band.

The optical activation energy of the electrons trapped by clusters or latent images is about 1.54 eV (electron volts) much lower than the −3 eV of bulk silver (see, for example, J. H. Webb, supra,). In the subsequent analysis by Baetzold (see, for example, R. C. Baetzold, J. Chern. Phys., 55 (1971) 4363, which is incorporated in its entirety by reference) of electron excitation from silver clusters, one finds that excitations of electrons from the highest occupied (HOMO) to the lowest unoccupied (LUMO) molecular orbitals to be between 1.8 and 2.4 eV for Ag5 and Ag4 clusters (e.g., clusters with five atoms or clusters with four atoms), respectively.

The optical radiation specifically He—Ne laser radiation at 632.8 nm (nanometers) or 1.96 eV pumps electrons from the silver clusters into higher energy levels or their LUMO states that are slightly higher than the e_{g}(π*) of the adsorbed Fe-TsPc. Electrons are transferred from excited LUMO states of silver clusters to the excited state of adsorbed Fe-TsPc and then to the final vibrational state of a₁ᵤ(π) with emission of the appropriate Raman line as shown in FIG. 3 or transition of ITO which Fermi level is equal to all Fermi levels of the Ag/M-TsPc/ITO sandwich. The charge transfer from LUMO->e_{g}(π*)->a₁ᵤ(π) with a higher population of e_{g}(π*) than a₁ᵤ(π), is similar if not identical to the population inversion mechanism involved in lasing. The high gain in photography and surface-enhanced Raman scattering may be related and determined by the ratio of the population numbers of N e_{g}(π*)/N a₁ᵤ(π).

A summary listing of the documents that are referred to specifically above and additional documents of interest is provided just below. The entire disclosures of those documents are incorporated by reference.
J. Billmann, G. Kovacs, and A. Otto, Sulj:Sci., 92 (1980) 153.
B. Simic-Glavaski, J. Phys. Chern, 90 (1986) 3863.
J. K. Gimzewski, J. H. Coombs, R. Moller, and R. R. Schlittler, in [5], 87.
B. Simic-Glavaski, A. A. Tanaka, M. E. Kenney, and E. Yeager, J. Electroanal. Chem., 229 (1987) 285.
T. H. Wood, Phys. Rev., B24 (1981) 2289.
W. Jaenicke, in Advances in Electrochemistry and Electrochemical Engineering, H. Gerischer and C. W. Tobias Eds., 10,91, John Wiley and Sons, New York, 1977.
J. H. Webb, J. Opt. Soc. Am., 40 (1950) 3.
R. C. Baetzold, J. Chern. Phys., 55 (1971) 4363.
D. A. Weitz, S. Garnoff, J. I. Gersten, and A. Nitzan, J. Chern. Phys., 78 (1983) 5324.

The photovoltaic device described herein has the capability to withstand temperatures, while still being operative to produce a photovoltaic response, in the range of from about 4 degrees K, e.g., the temperature of liquid helium, to a temperature that exceeds about 500 degrees Kelvin (250 degrees C.).

Phthalocyanines in particular are stable between liquid helium temperature and about 1,000 K degrees. A complex of phthalocyanine and clusters, for example, may be stable at temperatures above 500 K degrees, which silicon materials cannot withstand while maintaining stability. Such high temperatures occur, for example, in hot areas of deserts.

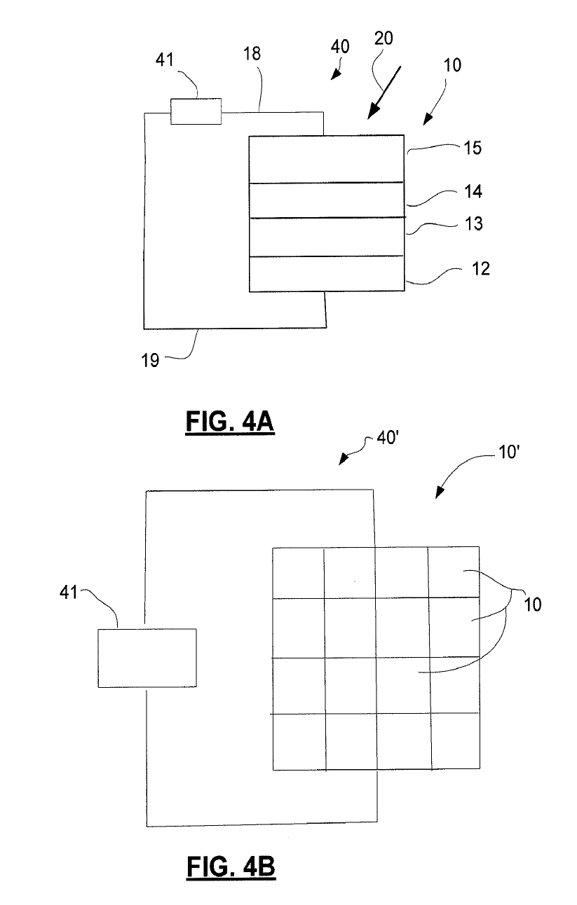

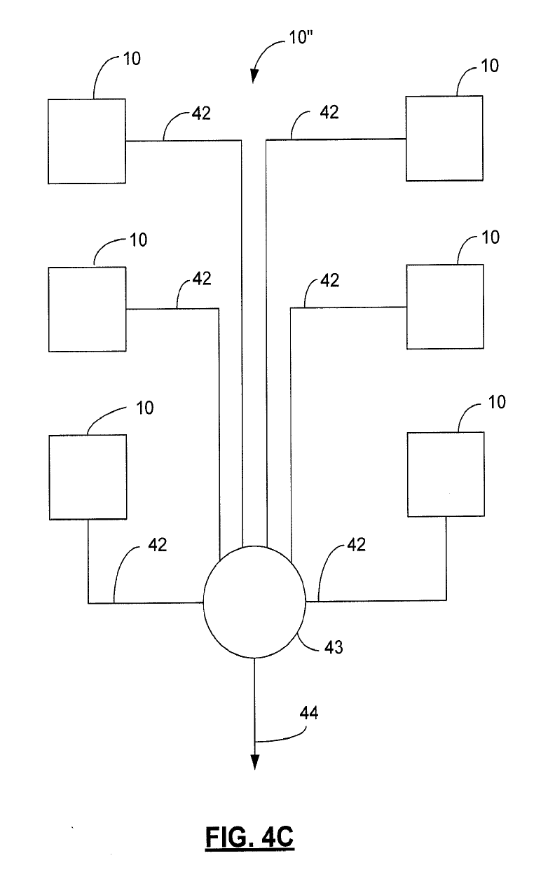

Referring to FIG. 4A, the photovoltaic device 10 is in a circuit 40 that has a load 41, e.g., a lamp (the terms lamp, light source, bulb, tube, and so on may be used equivalently and interchangeably herein), light emitting diode (LED), motor, and/or other circuit, load, device, and so on. In response to radiant energy 20 impinging on or incident on the photovoltaic device, a voltage is produced providing electrical energy to the load.

Thus, it will be appreciated that the photovoltaic device 10 transforms radiant energy to electrical energy that can be measured by the voltmeter 17 (shown in FIG. 2) and/or used to provide electrical energy or power to a load 41.

As is illustrated in FIG. 4B, a number of photovoltaic devices 10 may be assembled in a single photovoltaic unit 10′ that may be coupled in a circuit 40′ to provide electrical energy to a load 41. The several photovoltaic devices may be electrically coupled in various ways. One example is shown in FIG. 4C in which a device 10″ includes several photovoltaic devices 10 coupled electrical parallel by conductors 42 that are connected together at a junction or node 43 and then to an output 44. This is but one example of using a photovoltaic device 10 and of coupling plural photovoltaic devices 10. Other connection arrangements may be used for such systems or devices 10″ or for other systems or devices that employ one or more photovoltaic devices 10.

The combination of treating the bulk metal, such that at the surface the metallic state becomes a new structure where clusters are formed on the surface of the bulk metal together with the photovoltaic organo-metallic molecules, e.g., phthalocyanine molecules and/or porphyrin molecules, increases the efficiency of the photovoltaic effect of the organo-metallic molecules 14 transforming radiant energy into electricity. Moreover, due to the stable characteristics of the phthalocyanine molecules and porphyrin molecules, the photovoltaic device 10 is very stable.

For example, the described molecular devices, e.g., the photovoltaic devices described herein, e.g., using the M-Ph, M-Pc, and M-TsPc molecular systems described herein can withstand temperatures in the range of from that of liquid helium up to 1000 K, and also may withstand tough chemical conditions such as exposure to concentrated acids, and to electromagnetic radiations α, β, γ type. For example, the described molecular systems do not melt, change electrical properties or decompose when exposed to the mentioned harsh environment, e.g., acids or electromagnetic radiation, or hot or cold temperatures mentioned herein.

The bulk metal 11 may be any of silver, gold, copper, aluminum, or halides, such as silver bromide, which is mentioned above with respect to FIG. 3, or sodium chloride. The bulk metal is treated, e.g., as is described below, so as to cause the metallic state of the bulk metal at the surface to become a new structure of clusters at the surface. The organo-metallic molecules are on the clusters. The new structure of the clusters on the surface of the bulk metal increases the efficiency of the photovoltaic effect of the organo-metallic molecules 14.

It is possible that other bulk metal may be used, provided that suitable metallic clusters can be formed thereon so as would cooperate with the organo-metallic molecules to increase the efficiency of the photovoltaic effect of the organo-metallic molecules 14.

Examples of organo-metallic molecules include organo-metallic phthalocyanine molecules and organo-metallic porphyrin molecules. Examples of such molecules, include iron phthalocyanine molecules, cobalt phthalocyanine molecules and copper phthalocyanine molecules as well as organo-metallic porphyrin including such metals. The porphyrins may be less stable than the phthalocyanines.

Such organo-metallic molecules undergo photovoltaic effect in response to incident radiant energy.

Different organo-metallic molecules may have different absorption characteristics. The absorption characteristic is indicative of the wavelength(s) or wavelength range(s) of radiant energy that is absorbed by the organo-metallic molecule and corresponding voltage produced by the photovoltaic device. Thus, different types of organo-metallic molecules, may have different absorption characteristics. For example, different organo-metallic molecules may absorb light relatively efficiently and provide voltage output relatively efficiently at different respective wavelengths, groups of wavelengths or ranges of wavelengths.

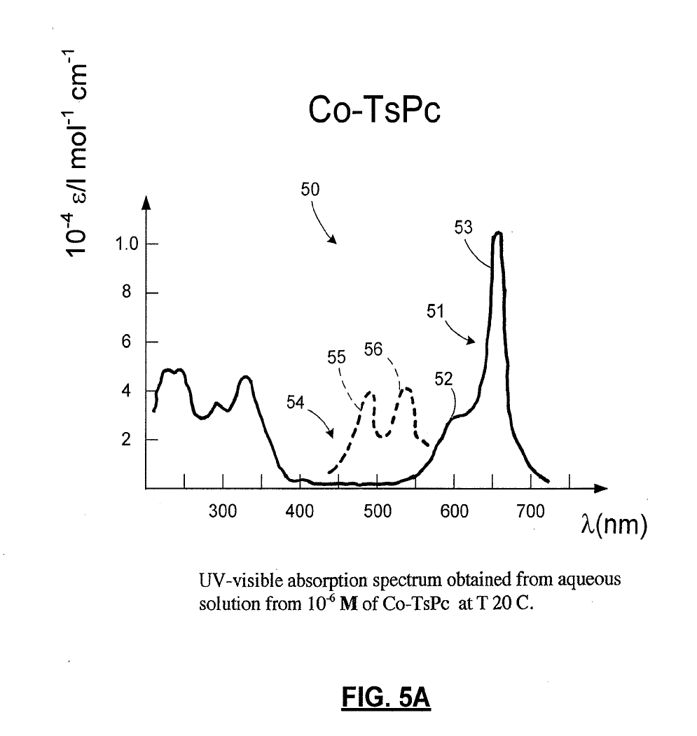

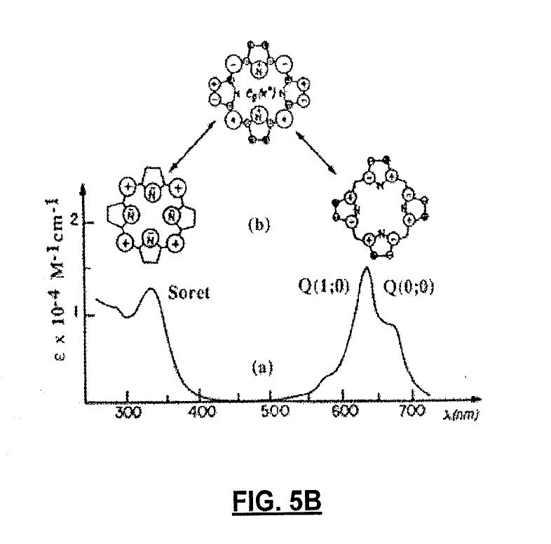

Referring to FIG. 5A, a graph 50 illustrating absorption characteristics of two exemplary organo-metallic molecules is illustrated. One of the organo-metallic molecules, which is represented by curve 51, is an aqueous solution from 10⁻⁶ M Co-TsPc (cobalt tetra-sulphonated phthalocyanine) at 20 degrees C. The vertical axis indicates the electrical output or response in electron volts (eV), which is shown along the axis as current I, and the horizontal axis indicates wavelength in nanometers (nm). In response to incident radiant energy along a range of wavelengths from part way into the ultraviolet wavelength region through the visible wavelength region, e.g., from about 300 nm (nanometers) to about 700 nm, there are different respective absorption peaks. For example, in the curve 51 one peak 52 is at about 550 nm and another peak 53 is at about 625 nm that would provide a region at or between those wavelengths at which an electrical output would be provided. The curve 54 in FIG. 5A may represent the absorption peaks 55 at about 475 nm and 56 at about 525 nm identifying the wavelengths or region at or between which an electrical output would be provided. Thus, using both organo-metallic molecules that provide absorption peak curves 51, 54 in a device 10, for example, the region of wavelengths over which electrical output of at least a desired magnitude would be produced would be greater than if only a single one of the organo-metallic molecules were used. In the regions of curves 51 and 54 are at or near zero eV, the device 10 would not provide any or not an acceptable electrical output for the desired purpose of using the device 10.

FIG. 5B is a typical UV (ultraviolet light) to visible absorption spectrum obtained from 10⁻⁶ M Co-TsPc in water, pH-7; (b) distribution of electrons responsible for the absorption Soret and Q bands; (c) electronic transitions for various macrocycle structures. In reference to the UV to Visible spectra Action Spectra (photo current generated from the same species of the phtalocyanine versus wavelength) follow the same curve of the absorption spectra, as is seen in FIG. 5B, which also is described further below.

In an embodiment the photovoltaic device 10 includes a number of organo-metallic molecules of different types that have different absorption characteristics, such as both types of organo-metallic molecules represented in the graph 50 with curves 51, 54 of FIG. 5A, and possibly others, too, so as to cover a relatively wide range of absorption characteristics. As can be seen from the graphical representation in FIGS. 5A and 5B, the wavelength absorption peaks (absorption characteristics) of the number of different types of organo-metallic molecules provide a number of discrete wavelengths or range of wavelengths at which the photovoltaic device 10 will efficiently produce suitable voltage output. Therefore, the photovoltaic device 10 may produce a suitable voltage output at or in the region of a relatively large number of wavelengths and/or ranges of wavelengths. A suitable voltage output may be subjectively quantified as a voltage output that is adequate for the task for which the use of the photovoltaic device 10 is intended. For example, the task may be to provide sufficient electrical energy to power a given load 41 (FIG. 4B). It will be appreciated that the photovoltaic device 10 may be a single photovoltaic device or a plurality of photovoltaic devices, which are connected together, to provide the suitable voltage output.

Reference herein to a given wavelength may indicate a specific wavelength or a specific wavelength and a small region of wavelengths that are relatively near the specific wavelength. This is exemplified by the curvature in the curves 51, 54 of the graph 50 (FIG. 5A) at the absorption peaks in FIG. 4. As compared to such a region, a range of wavelengths may be a number of specific wavelengths and/or a number of specific wavelengths and the relatively near regions of respective specific wavelengths. The number of specific wavelengths, the width or breadth of regions associated with specific wavelengths of absorption peaks may depend on the particular organo-metallic molecule(s) and characteristics thereof that are used in the photovoltaic device.

In response to radiant energy, which is absorbed by the organo-metallic molecules, holes and electrons are produced in the organo-metallic molecules. The holes tend to migrate to the conductor 15 and the electrons tend to migrate to the bulk metal 11. Thus, electric potential is provided by the photovoltaic device 10, for example, in a circuit 16 (FIG. 3) such that the conductor 15 and lead 18 are relatively positive and the base metal 11 and lead 19 are relatively negative, e.g., relative ground.

As was mentioned above, the organo-metallic molecules may be a mix of a number of different types of organo-metallic molecules, the respective types having different respective wavelength absorption characteristics. The mix may include only phthalocyanine molecules, only porphyrin molecules, and/or a combination of phthalocyanine molecules and porphyrins molecules. The organo-metallic molecules may be selected to be of types that have different wavelength absorption peaks that together or collectively cover a relatively wide range of wavelengths, that cover a specific relatively small range of wavelengths, or that cover some other desired wavelength, wavelength range, and/or group of wavelengths as to be responsive to provide efficient photovoltaic effect at that/those wavelengths.

By providing a wide range of wavelength absorption characteristics for the photovoltaic device 10, an efficient photovoltaic effect and, thus, voltage output, will be provided in response to a wide range of wavelengths of light. For example, during the course of a day, the wavelength characteristics of incident sunlight may change, yet a wide wavelength range photovoltaic device efficiently will provide efficient voltage output, for example, as the day begins, brightens, and wanes and/or wavelength of incident light changes, which may depend on various conditions, e.g., angle of the incident sunlight through the atmosphere, other atmospheric conditions, and so on. Moreover, the photovoltaic device 10 may be made with organo-metallic molecules to provide efficient voltage output in response to both sunlight and artificial light, to artificial light that is from different respective light sources, e.g., incandescent lamps, light emitting diodes (LEDs), fluorescent lamps, and so on. Alternatively, the photovoltaic device 10 can be made with organo-metallic molecules that provide efficient photovoltaic effect at one wavelength or wavelength range, e.g., light from an incandescent lamp, and does not provide efficient photovoltaic effect at a different wavelength or wavelength range, e.g., light from a fluorescent lamp.

The organo-metallic molecules 14 may be phthalocyanine molecules or porphyrin molecules, both being of the type that undergo photovoltaic effect in response to radiant energy impinging thereon. As was mentioned above, different organo-metallic molecules may have different absorption characteristics. Thus, the different organo-metallic molecules may respond differently to radiant energy of different respective wavelengths.

Exemplary phthalocyanine molecules are metallo-phthalocyanine molecules. Such molecules include a metal, such as, for example, iron, cobalt or copper, and others, and the molecules are referred to as iron phthalocyanine, cobalt phthalocyanine and copper phthalocyanine, respectively. Since the phthalocyanine molecules are organic molecules, such molecules that include metal may be referred to as organo-metallic molecules. The photovoltaic device 10 may include a mix that includes iron phthalocyanine molecules, copper phthalocyanine molecules and cobalt phthalocyanine molecules, each of which has different absorption characteristics and, therefore, provides for the photovoltaic device a relatively large spectrum of absorption peaks to provide suitable electrical output over that relatively large spectrum or range of wavelengths. Additionally, the mix may include one or more types of porphyrin molecules and other types of phthalocyanine molecules.

The conductor 15 may be electrically conductive material that is transparent to radiant energy to which it is intended that the organo-metallic molecules 14 respond to provide photovoltaic effect. Exemplary conductors 15 may be indium tin oxide (ITO). ITO is a well-known transparent conductor that has been used to apply electric field across liquid crystal material in liquid crystal cells of liquid crystal displays. Other transparent conductors include an ionomer material, an example of which is tetrafluoroethylene based fluoropolymer-copolymer, and another example of which is sold under the trademark NAFION®. NAFION material is an electrolyte that has some characteristics that are similar to TEFLON® material.

The conductor 15 sometimes may be referred to as an electrode. The conductor would be of a material that is suitably electrically conductive such that an electric potential or voltage can be obtained as output from the photovoltaic device 10 via a connection to the conductor and a connection to the base metal 11 in response to the organo-metallic molecules undergoing photovoltaic response to incident radiant energy. The conductor 15 would be sufficiently transparent or sufficiently thin and, thus, be sufficiently transparent to pass the radiant energy therethrough to the organo-metallic molecules.

Several methods for making clusters 13 on the bulk metal 11 are described here.

### Example 1

The clusters may be, for example, 1, 2, 3 or even 10 atoms of metal, i.e., of the bulk metal 11. The atoms for the cluster are obtained by placing polycrystalline bulk silver into hydrogen peroxide that is about 30% by volume water for a period of time. In one embodiment the period of time is from about 20 seconds to about one minute. In another embodiment, the time period is from about 30 seconds to about one minute.

### Example 2

Polycrystallinie bulk silver is placed into a liquid electrolyte that is from about 0.05 to about 0.1 molar sulfuric acid or hydrochloric acid. The bulk silver is kept at a potential of from about 0.2 volts to about 0.5 volts vs. a saturated calomel electrode (SCE) for a period of time. In one embodiment the time period is from a few seconds to about one minute.

### Example 3

The bulk metal, e.g., silver, copper or gold, is placed in an electrolyte, such as, for example about 0.1 M of perchloric acid or about 0.05 M H₂SO₄

The potential is kept at the hydrogen evolution potential, which is about 1.5 volts, for a time period. The time period in one embodiment is from about several seconds to about 1 minute.

### Example 4

Photooxidation of the base metal is used to form clusters on the base metal.

In each of the above examples 1, 2, 3 and 4, after the clusters are provided on the base metal, the organo-metallic molecules are applied to the clusters, and the electrode is applied to form the device 10, e.g., as it is illustrated generally in FIGS. 1 and 2.

The electrical and optical properties of phthalocyanine molecules are strongly dependent on structural configuration. The general properties of phthalocyanine molecules have been presented and discussed in other reports; however, some fundamental and relevant properties are presented again here. The basic 18π electron structure in metal free and other metallo phthalocyanine molecules has very rich molecular orbitals and available energy levels. The populated ground HOMO and SHOMO levels are a1u(π) and a2u(π) and the excited LUMO level is e.g. (π*). The electronic transitions a1u(π)--->e.g. (π*) and a2u(π)--->e.g. (π*) are responsible for the intense visible absorption Q and ultraviolet Soret bands, positioned at about 660 and 330 nm respectively. The Q absorption band splits into Q(O,O) and Q(l.O) as a result of vibrational conditions. An example of the absorption spectrum obtained from cobalt tetra-sulphonated phthalocyanine (Co-TsPc) is shown in FIGS. 5A and 5B.

Referring to FIG. 5B again, the distributions of molecular charge is presented with the most representative intermolecular charge transfers. The absorption spectrum is characteristic of phthalocyanine molecules, regardless of whether it is obtained from water-soluble forms, like tetra-sulphonated forms, or from ring-stacked or polymeric configurations.

An advantage of organic cells in the extension of light absorbance in visible region of the spectrum ease in fabrication and lower cost.

One of the fabrication methods involves water soluble M-TsPc where M is usually Zn or H2. In order to increase contact between M-TsPc and ITO TiO2 nanostructure was developed on ITO. Microstructure of TiO2 was obtained from colloidal suspension using hydrolysis of tetrabutyl titanate (C4H9O)4Ti polyvinyl alcohol (PVA) was added to suspension, which was than concentrated by vacuum evaporation. Before TiO2 was deposited on ITO a Triton monolayer was formed on ITO by Langmuir method deposition. Concentrated TiO2 was prepared in another Langmuir trough and ITO with a Triton monolayer was dipped thus forming 90% transparent electrode. The working electrode was obtained by placing TiO2 into a 5×10−4 M Zn-TsPc in dimethyl sulfoxide (DMSO) for 1 h. To form the final cell, a drop of liquid electrolyte 0.1 M KI and 0.05 m I in 0.001M HClO4 solution. This structure was capped by ITO electrode where a thin layer of Pt was added. See figure in which such system 20% of light is harvested.

### Example 5

### Fabrication Method of Sandwiched Cells

A sandwich cell (photovoltaic device 10) of the type illustrated in FIGS. 1 and 2, for example, is formed of indium tin oxide, tetra-sulphonated metallo-phthalocyanine and a base metal (abbreviated ITO/M-TsPc/Me). The base metal may also be considered an electrode, whereby in use of the device 10, electric potential is provided across the ITO and the base metal. In this example, the base metal (electrode) is silver (Ag) or gold (Au).

The base metal is a thin foil, e.g., similar to tin foil, of silver. Alternatively, the base metal is silver deposited on flexible Mylar.
a) The silver electrode (i.e., the base metal) is exposed to a solution of “Pyrana” 70:30% concentrated sulfuric acid H2SO4 and H2O2 30% volume concentration. The Ag electrode is exposed 30-60 seconds and then washed in distilled water.
   This procedure forms silver clusters on the base metal. Surface contact is increased and the silver work function is reduce from 3.6 to 1.8 eV. The same process and effect can be obtained using gold (Au) as the base metal.
b) The silver electrode is exposed for 30 seconds in 30% volume H2O2.
c) After that exposure, the silver electrode is washed in distilled water and dried
d) The organic metallo molecules may be applied to the clusters that are formed on the base metal; and then the ITO layer is applied to the organic metallo molecules.

### Example 6

### Electrochemical Method of Cluster Formation

A cleaned and polished silver polycrystalline electrode of 99.99% purity is submerged in 0.01M HClO4 electrolyte and submitted to electrochemical cyclic voltammetry between −0.6-0.2 V versus SCE (saturated calomel electrode) reference electrode where Au (gold) is a counter electrode. After several cycles (10-20) 0.5 V potential is applied and the electrode is left for 50 seconds. Afterwards that electrode is washed in distilled water and left to dry.

In order to reduce cost the polycrystalline silver electrode can be replaced by depositing silver layer of about one thousand angstroms (Å) on Mylar or by silver-plating on less expensive conductors such as zinc (Zn) or aluminum (Al).

### Example 7

### Electrochemical Method Cluster Formation on Gold

Polycrystalline gold electrode of 99.99% purity in the form of thin foil is cleaned in 1M H2SO4 and washed in distilled water, and then is placed in 0.1 M KCl electrolyte and is submitted to cyclic voltammetry, as follows:
a) first potential E1 of −0.5 V (volts) for 60 second
b) a ramp potential of V1=1 V/sec to
c) E2 potential of 1.2 V for two seconds, and then to
d) a declining potential ramp V2=0.5V/sec to the original potential E1.

This is repeated 20-100 times.

After that procedure the electrode is washed in distilled water leaving the gold electrode with gold clusters at the surface.

### Example 8

Applying solutions of phthalocyanines and porphyrins and ITO to the clusters that are on the base metal as described, for example, in Examples 5, 6, 7 and 8 above as well as in the earlier described Examples 1, 2, 3 and 4.

A solution of electrolyte 0.01.M HClO4 containing from about 10⁻³M to about 10⁻⁵ M of water soluble M-TsPc or porphyrin molecules M-Pc is spread (e.g., spin coating or simple brushing) on silver or gold electrodes and then is capped with ITO. The edges are sealed to prevent evaporation. In order to increase of the number of and/or range of absorption spectrum/spectra the organo-metallic molecules may be a mixture of various M-TsPc or porphyrins or even combination of M-TsPc/M-Pc.

Specific embodiments of an invention are disclosed herein. One of ordinary skill in the art will readily recognize that the invention may have other applications in other environments. In fact, many embodiments and implementations are possible. The following claims are in no way intended to limit the scope of the present invention to the specific embodiments described above. In addition, any recitation of “means for” is intended to evoke a means-plus-function reading of an element and a claim, whereas, any elements that do not specifically use the recitation “means for”, are not intended to be read as means-plus-function elements, even if the claim otherwise includes the word “means”.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

1. A photovoltaic device comprising
bulk metal having a surface,
metallic clusters on the surface of the bulk metal,
organo-metallic molecules on the metallic clusters and responsive to radiant energy to undergo photovoltaic effect.

2. The device of claim 1, further comprising
a conductor in position relative to the organo-metallic molecules to pass radiant energy to the organo-metallic molecules,
whereby in response to radiant energy the organo-metallic molecules undergo photovoltaic effect transforming radiant energy to electric potential, and wherein the organo-metallic molecules and the metal clusters are cooperative to increase the efficiency of the photovoltaic effect.

3-9. (canceled)

10. The device of claim 1, wherein the organo-metallic molecules comprise a number of different types of organo-metallic molecules, the respective types having different respective wavelength absorption characteristics.

11. The device of claim 10, wherein the wavelength absorption characteristics are wavelength absorption peaks, and the photovoltaic voltage output characteristics of respective organo-metallic molecules at least generally correspond to respective wavelength absorption peaks.

12-13. (canceled)

14. The device of claim 1, wherein the organo-metallic molecules comprise phthalocyanine molecules, and phthalocyanine molecules comprises metallophthalocyanine molecules.

15. (canceled)

16. The device of claim 1, wherein the organo-metallic molecules comprise porphyrin molecules.

17. The device of claim 1, wherein the organo-metallic molecules comprise a mixture of phthalocyanine molecules and porphyrin molecules.

18. The device of claim 1, wherein the organo-metallic molecules are responsive to radiant energy in the visible light spectrum.

19. (canceled)

20. The device of claim 1, wherein the device is capable of withstanding temperatures while still being operative to produce a photovoltaic response at a temperature that exceeds 500 degrees Kelvin.

21. A photovoltaic unit comprising a plurality of photovoltaic devices as set forth in claim 1, the photovoltaic devices coupled together to provide electrical output.

22-24. (canceled)

25. A method of forming clusters on a base metal, comprising placing polycrystalline bulk silver into a liquid electrolyte that is from about 0.05 to about 0.1 molar sulfuric acid or hydrochloric acid, the bulk silver is kept at a potential of from about 0.2 volts to about 0.5 volts vs. a saturated calomel electrode (SCE) for a period of time.

26-28. (canceled)

29. A method of forming clusters on a base metal, comprising exposing the base metal to photooxidation to form the clusters on the base metal.

30. (canceled)

31. The method of claim 29, further comprising after the clusters are provided on the base metal, applying organo-metallic molecules to the clusters, and further comprising applying an electrode to the organo-metallic molecules to form a photovoltaic device.

32. The method of claim 31, wherein the organo-metallic molecules comprise at least one organo-metallic phthalocyanine, organo-metallic porphyrin, tetra-sulphonated metallo-phthalocyanine or a combination of one or more thereof having different absorption peaks.

33. A method of making a sandwich cell of a photovoltaic device that comprises indium tin oxide, tetra sulphonated metallo-phthalocyanine and a base metal electrode of silver or gold, comprising,
Forming metal clusters on the base metal electrode by exposing the base metal electrode to a solution of “Pyrans” 70:30% concentrated sulfuric acid H2SO4 and H2O2 30% volume concentration for from about 30 seconds to about 60 seconds, and then washing the base metal in distilled water, and
Applying organic-metallo molecules to the clusters that are formed on the base metal; and
Applying a conductor layer to the organic-metallo-molecules.

34. The method of claim 33, wherein applying a conductor layer comprises applying ITO.

35-39. (canceled)

40. A method of forming a cluster on a gold electrode, comprising,
Cleaning the gold electrode in sulfuric acid (H2SO4),
Washing the cleaned gold electrode in distilled water,
Placing the gold electrode in an electrolyte and submitting it to cyclic voltammetry, and then
Washing the gold electrode metal in distilled water, leaving the gold electrode with gold clusters at the surface.

41-42. (canceled)

43. The method of claim 40, wherein said submitting to cyclic voltammetry comprises
Submitting to
a) first potential E1 of −0.5 V (volts) for about 60 seconds
b) a ramp potential of V1=1 V/sec to
c) E2 potential of 1.2 V for two seconds, and then to
d) a declining potential ramp V2=0.5V/sec to the original potential E1.

44. (canceled)

45. The method of claim 29, further comprising applying metallo organic molecules to the clusters, comprising
applying solutions of phthalocyanines and porphyrins and ITO to the clusters that are on the base metal electrode, including
spreading a solution of electrolyte about 0.01.M HClO4 containing from about 10⁻³M to about 10⁻⁵ M of water soluble M-TsPc or porphyrin molecules M-Pc is spread (e.g., spin coating or simple brushing) on clusters on the silver or gold electrodes and then applying a cap of ITO.

46-47. (canceled)

48. The method of claim 45, comprising increasing the number of and/or range of absorption spectrum/spectra by selecting the organo-metallic molecules as a mixture of plural M-TsPc, porphyrin or even combination of M-TsPc/M-Pc that have different absorption peaks.
